(19) United States
(12) Patent Application Publication
(10) Pub. No.: US 2022/0229580 A1
(43) Pub. Date: Jul. 21, 2022

(54) TEMPERATURE TRACKING FOR A MEMORY SYSTEM

(71) Applicant: Micron Technology, Inc., Boise, ID (US)

(72) Inventor: David Aaron Palmer, Boise, ID (US)

(21) Appl. No.: 17/153,547

(22) Filed: Jan. 20, 2021

(51) Int. Cl. G06F 3/06

(52) U.S. Cl. CPC G06F 3/0653; G06F 3/0604; G06F 3/0679; G06F 3/0655

(57) ABSTRACT

Methods, systems, and devices for temperature tracking for a memory system are described. A set of temperature ranges and a set of partitions of a memory system may be stored. Each temperature range of the set of temperature ranges may be mapped to one or more respective partitions of the set of partitions of the memory system. A command to read a partition of the set of partitions may be received. It may then be determined whether temperature data associated with the set of temperature ranges for the partition indicates that data was written to the partition outside a threshold temperature. Data may then be read from the partition based on having determined whether the temperature data associated with the set of temperature ranges indicates that the data was written to the partition outside of the threshold temperature.

### FIELD OF TECHNOLOGY

The following relates generally to one or more systems for memory and more specifically to temperature tracking for a memory system.

### BACKGROUND

Memory devices are widely used to store information in various electronic devices such as computers, wireless communication devices, cameras, digital displays, and the like. Information is stored by programing memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read, or sense, the state of one or more memory cells within the memory device. To store information, a component may write, or program, one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), ferroelectric RAM (FeRAM), magnetic RAM (MRAM), resistive RAM (RRAM), flash memory, phase change memory (PCM), 3-dimensional cross-point memory (3D cross point), not- or (NOR), and not- and (NAND) memory devices, and others. Memory devices may be volatile or non-volatile. Volatile memory cells (e.g., DRAM cells) may lose their programmed states over time unless they are periodically refreshed by an external power source. Non-volatile memory cells (e.g., NAND memory cells) may maintain their programmed states for extended periods of time even in the absence of an external power source.

### BRIEF DESCRIPTION OF THE DRAWINGS

FIG. 1 illustrates an example of a system that supports temperature tracking for a memory system in accordance with examples as disclosed herein.

FIG. 2 illustrates an example of a system that supports temperature tracking for a memory system in accordance with examples as disclosed herein.

FIG. 3 illustrates an example of a process flow that supports temperature tracking for a memory system in accordance with examples as disclosed herein.

FIG. 4 illustrates an example of a storage configuration that supports temperature tracking for a memory system in accordance with examples as disclosed herein.

FIG. 5 shows a block diagram of a memory system that supports temperature tracking for a memory system in accordance with examples as disclosed herein.

FIG. 6 shows a flowchart illustrating a method or methods that support temperature tracking for a memory system in accordance with examples as disclosed herein.

### DETAILED DESCRIPTION

Memory systems and devices may have a different reliability, among other aspects, if operating at different temperatures. For example, data written to and stored in a memory device at a relatively different temperature than some nominal or threshold temperature, or outside of some nominal or threshold range (e.g., hotter or colder operating conditions relative to some nominal temperature) may be less reliable than the same data stored to the same memory device at or near that nominal temperature or within the nominal temperature range. Some memory devices, such as non-volatile memory devices (e.g., not- and (NAND) memory devices such multi-level memory devices including tri-level cell (TLC) memory devices or quad level cell (QLC) memory devices, among other examples), may be relatively more susceptible to temperature variation affecting the reliability of data written to the memory device (e.g., more susceptible than a single level cell (SLC) memory devices). For such memory device, recording the temperature at which data is written may be beneficial to mitigate otherwise-poor reliability of the data. For example, where the recorded temperature information indicates that certain data was written outside of a nominal temperature range (e.g., higher or lower than the nominal temperature range), the memory system may perform one or more compensation procedures on the data written to the memory device. Such compensation procedures may be performed during a read operation for the data to account for a temperature difference (e.g., a delta) that may exist between when the read operation occurred and when the write operation occurred, or otherwise manage the reduced reliability for the data during storage. The temperature data may be stored may be stored as metadata. However, storing the temperature data as metadata in the same memory device as the temperature data, the metadata may be subject to similar temperature reliability issues as the stored data. Moreover, it may be inefficient to scan the metadata for all data on a memory device, for example to identify and relocate reduced reliability data. Additionally, such stored metadata may break or otherwise render ineffective some blind copy operations, such as copyback operations. For example, copyback operations or other operation) may fail to update the metadata, such that the temperature metadata may not accurately track the temperature information for the related data following the operation (e.g., if the data is rewritten or otherwise changed and the temperature metadata is unchanged).

According to the techniques described herein, temperature data may be stored for a set of partitions (e.g., a set of blocks, a set of virtual blocks, a set of pages, a set of virtual pages, a set of memory devices, or other subset or groupings) corresponding to one or more memory devices, for example, of a memory system. Each partition of the set of partitions may be associated with a corresponding set of temperature ranges in some examples. A set of partitions and corresponding temperature ranges may, in some examples, be referred to as a temperature tracking table although other associations of such partitions and temperature ranges can be used with the techniques described herein. As data is written to a particular partition, information, such as a bit, may be assigned to one or more of the temperature ranges that correspond to the observed or sensed temperature at the time of writing to indicate that the partition contains data that was written in that temperature range. If data is to be read from the partition, the set of temperature ranges for the partition may be checked to determine related temperature data, such as if the partition contains data that was written outside the nominal temperature range. The memory system may then perform temperature compensation based on the temperature data, selective garbage collection based on the temperature data, or both, among other examples. In some examples, based on the temperature data, the memory system may relocate or rewrite data written outside the nominal temperature range based on one or more conditions, such as once the temperature has returned to a nominal temperature or is otherwise within a nominal range, or is relatively closer to a nominal temperature or a nominal range relative to the temperature when the data was written outside the nominal temperature range, among other examples.

The techniques described herein may allow for efficient tracking of reduced reliability data in a memory system. A temperature tracking table may use relatively fewer resources (e.g., memory, computation) and be simpler to implement and be more reliable than other techniques, such as storing temperature data in metadata. Temperature tracking as described herein, such as using a temperature tracking table, may also provide efficient initial checking for stored data, for example to determine whether additional temperature compensation may be needed for data to be read out of a memory device. Moreover, the temperature tracking techniques and table described herein may allow for the use of blind copy operations, such as copyback operations, on the stored data, for example for temperature-sensitive memory devices. Such blind copy operations may be otherwise unavailable for use in temperature sensitive devices.

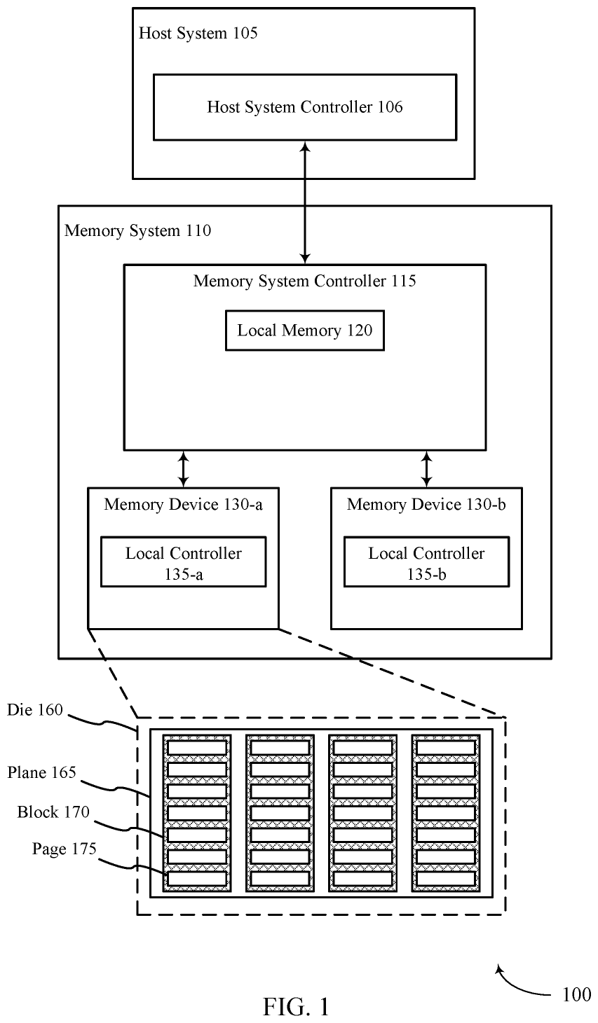

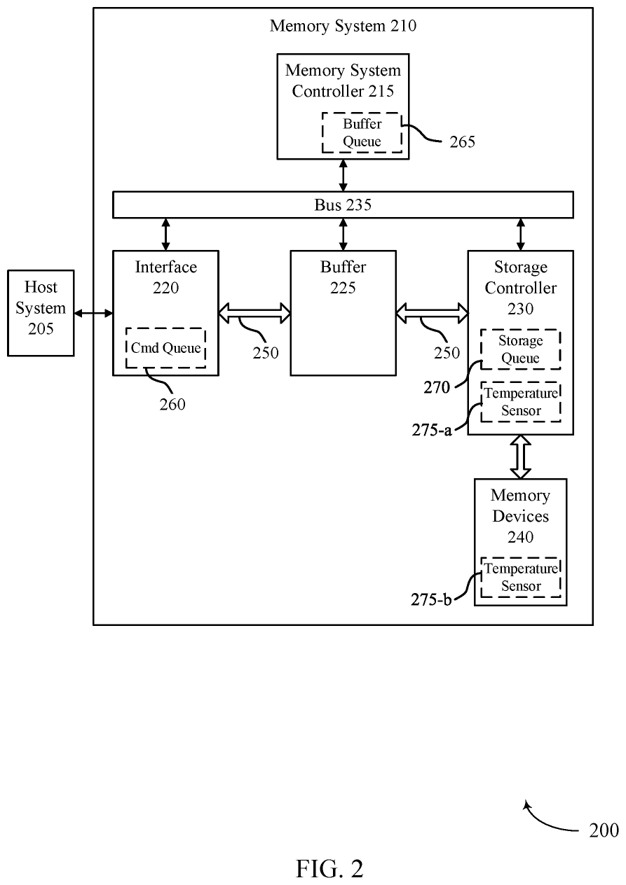

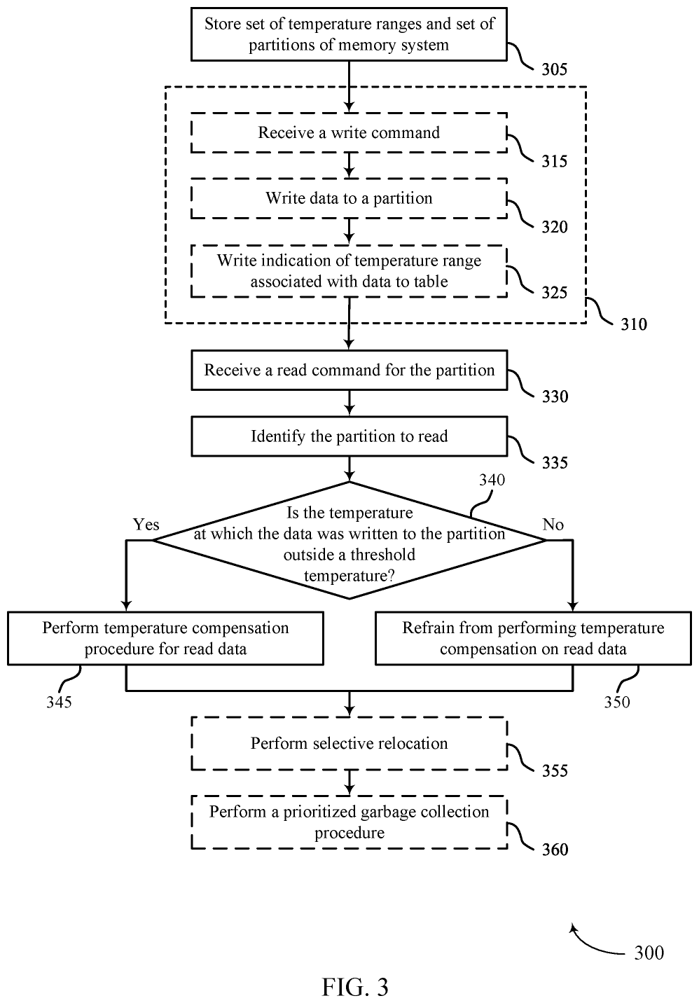

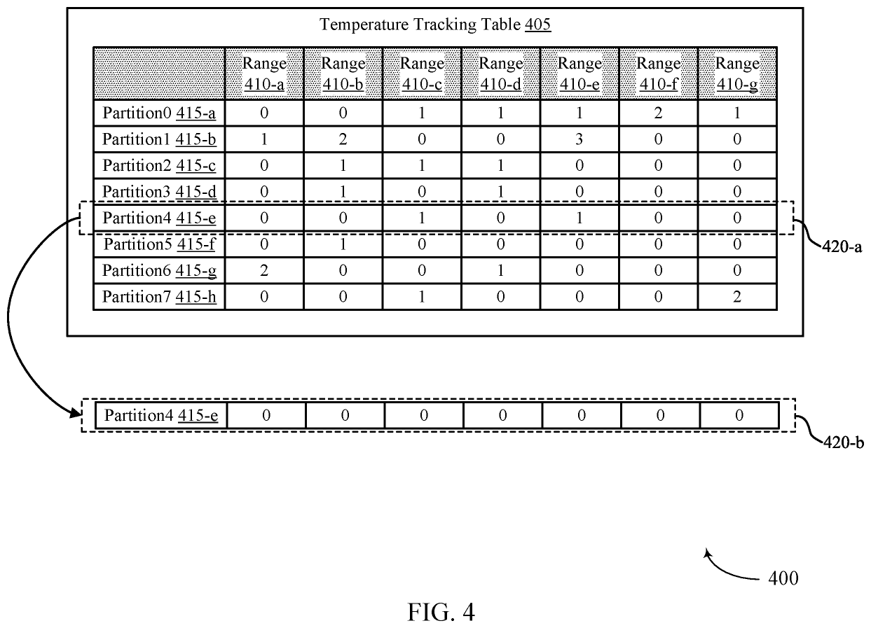

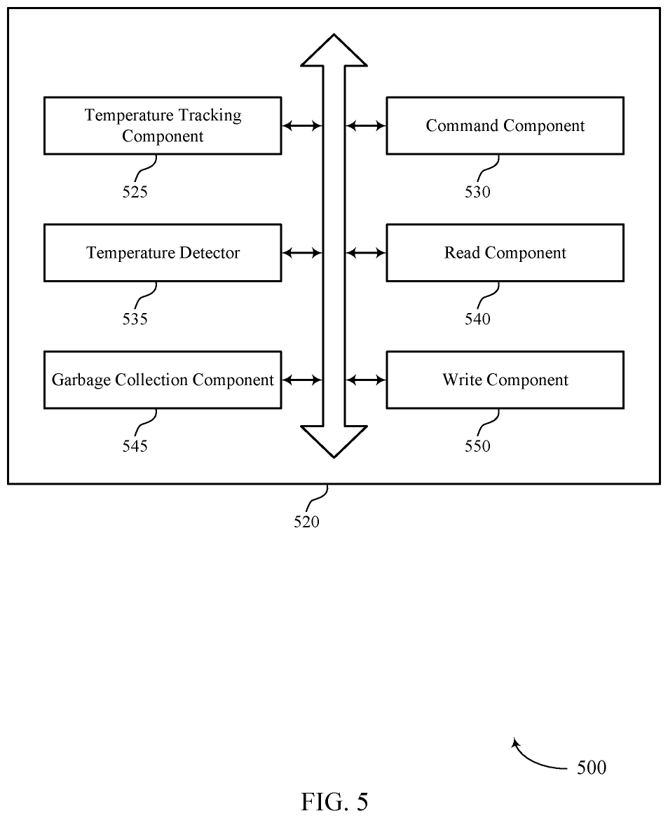

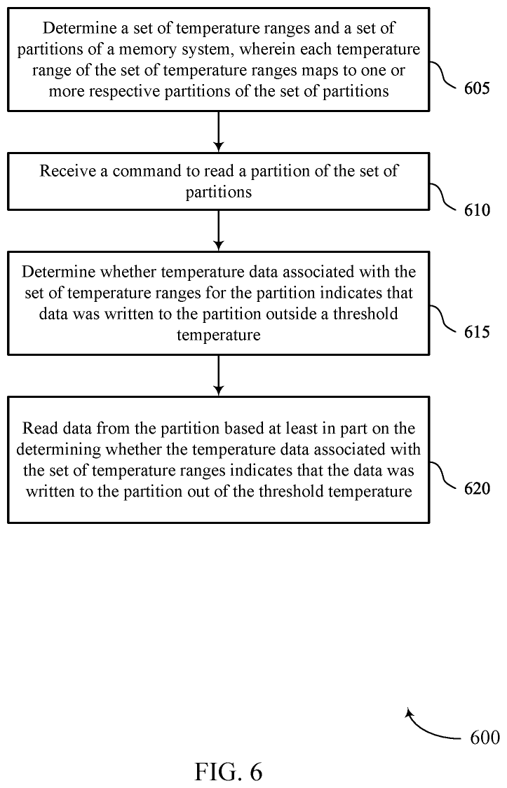

Features of the disclosure are initially described in the context of systems, devices, and circuits as described with reference to FIGS. 1 and 2. Features of the disclosure are described in the context of process flows and a storage configuration as described with reference to FIGS. 3 and 4. These and other features of the disclosure are further illustrated by and described with reference to an apparatus diagram and flowcharts that relate to temperature tracking for a memory system as described with reference to FIGS. 5 and 6.

FIG. 1 is an example of a system 100 that supports temperature tracking for a memory system in accordance with examples as disclosed herein. The system 100 includes a host system 105 coupled with a memory system 110.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other possibilities.

The system 100 may be included in a computing device such as a desktop computer, a laptop computer, a network server, a mobile device, a vehicle (e.g., airplane, drone, train, automobile, or other conveyance), an Internet of Things (IoT) enabled device, an embedded computer (e.g., one included in a vehicle, industrial equipment, or a networked commercial device), or any other computing device that includes memory and a processing device.

The system 100 may include a host system 105, which may be coupled with the memory system 110. In some examples, this coupling may include an interface with a host system controller 106, which may be an example of a control component configured to cause the host system 105 to perform various operations in accordance with examples as described herein. The host system 105 may include one or more devices, and in some cases may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may in some cases be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or any combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally or alternatively include static random access memory (SRAM) or other memory that may be used by the memory system controller 115 for internal storage or calculations, for example, related to the functions ascribed herein to the memory system controller 115. Additionally or alternatively, the local memory 120 may serve as a cache for the memory system controller 115. For example, data may be stored in the local memory 120 if read from or written to a memory device 130, and may be available within the local memory 120 for subsequent retrieval for or manipulation (e.g., updating) by the host system 105 (e.g., with reduced latency relative to a memory device 130) in accordance with a cache policy.

Although the example of memory system 110 in FIG. 1 has been illustrated as including the memory system controller 115, in some cases, a memory system 110 may not include a memory system controller 115. For example, the memory system 110 may additionally or alternatively rely upon an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may in some cases instead be performed by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric RAM (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), and electrically erasable programmable ROM (EEPROM). Additionally or alternatively, a memory device 130 may include one or more arrays of volatile memory cells. For example, a memory device 130 may include random access memory (RAM) memory cells, such as dynamic RAM (DRAM) memory cells and synchronous DRAM (SDRAM) memory cells.

In some examples, a memory device 130 may include (e.g., on a same die or within a same package) a local controller 135, respectively, which may execute operations on one or more memory cells of the memory device 130. A local controller 135 may operate in conjunction with a memory system controller 115 or may perform one or more functions ascribed herein to the memory system controller 115.

In some cases, a memory device 130 may be or include a NAND device (e.g., NAND flash device). A memory device 130 may be or include a memory die 160. For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some examples, a memory device 130 may operate according to virtual blocks and virtual pages. A virtual block may correspond to one block 170 off each plane 165 and each NAND die 160. Each virtual block may include multiple virtual pages. In some cases, multiple virtual pages may correspond to a physical page 175 (e.g., four virtual pages per physical page 175). In some examples, a virtual block may include tens of thousands of virtual pages (e.g., depending on the size of the memory device 130). The memory device 130 may perform read and write operations according to the virtual blocks and virtual pages. In some examples, one or more virtual pages, virtual blocks, pages 175, blocks 170, or memory devices 130 may be referred to as a “partition” or a “subset” of a memory system 110.

In some cases, a NAND memory device 130 may include memory cells configured to each store one bit of information, which may be referred to as SLCs. Additionally or alternatively, a NAND memory device 130 may include memory cells configured to each store multiple bits of information, which may be referred to as multi-level cells (MLCs) if configured to each store two bits of information, as TLCs if configured to each store three bits of information, as QLCs if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170, and in some cases, concurrent operations may take place within different planes 165. For example, concurrent operations may be performed on memory cells within different blocks 170 so long as the different blocks 170 are in different planes 165. In some cases, performing concurrent operations in different planes 165 may be subject to one or more restrictions, such as identical operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in a same page 175 may share (e.g., be coupled with) a common word line, and memory cells in a same string may share (e.g., be coupled with) a common digit line (which may alternatively be referred to as a bit line).

For some NAND architectures, memory cells may be read and programmed (e.g., written) at a first level of granularity (e.g., at the page level of granularity) but may be erased at a second level of granularity (e.g., at the block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may in some cases not be updated until the entire block 170 that includes the page 175 has been erased.

In some cases, to update some data within a block 170 while retaining other data within the block 170, the memory device 130 may copy the data to be retained to a new block 170 and write the updated data to one or more remaining pages of the new block 170. The memory device 130 (e.g., the local controller 135) or the memory system controller 115 may mark or otherwise designate the data that remains in the old block 170 as invalid or obsolete, and update an L2P mapping table to associate the logical address (e.g., LBA) for the data with the new, valid block 170 rather than the old, invalid block 170. In some cases, such copying and remapping may be used instead of erasing and rewriting the entire old block 170, due to latency or wearout considerations, for example. In some cases, one or more copies of an L2P mapping table may be stored within the memory cells of the memory device 130 (e.g., within or more blocks 170 or planes 165) for use (e.g., reference and updating) by the local controller 135 or memory system controller 115.

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the number of blocks 170 that have been erased may be increased such that more blocks 170 are available to store subsequent data (e.g., data subsequently received from the host system 105).

Temperature data may be stored for a set of partitions corresponding to one or more memory devices 130, for example, of a memory system 110. Each partition may be associated with a corresponding set of temperature ranges in some examples. A set of partitions and corresponding temperature ranges may, in some examples, be referred to as a temperature tracking table although other associations of such partitions and temperature ranges can be used with the techniques described herein. In some examples, such temperature tracking table or other associations, including the associated temperature data, may be stored in memory system 110, for example in local memory 120 of memory system controller 115. As data is written to partitions, information, such as a bit, may be assigned to one or more of the temperature ranges that corresponds to the observed or sensed temperature at the time of writing to indicate that the partition contains data that was written in that temperature range. If data is to be read from the partition, the set of temperature ranges for the partition may be checked to determine related temperature data, such as if the partition contains data that was written outside the nominal temperature range. In some example, the memory system 115 may then perform temperature compensation based on the temperature data. Additionally or alternatively, in some examples, based on the temperature data, the memory system may relocate or rewrite data written outside the nominal temperature range based on one or more conditions, such as once the temperature has returned to a nominal temperature or is otherwise within a nominal range, or is relatively closer to a nominal temperature or a nominal range relative to the temperature when the data was written outside the nominal temperature range, among other examples. Additionally or alternatively, the memory system 115 may perform selective garbage collection based on the temperature data.

In some examples, in selective garbage collection, the memory system 115 may determine that some partitions include data written outside the of a nominal temperature range. For example, memory system controller 115 may read a temperature tracking table or other association from local memory 120, to identify one or more partitions with data written outside the nominal temperature range. For example, within a memory device 130, a block 170 may have some pages 175 containing valid data and some pages 175 containing invalid data. To avoid waiting for all of the pages 175 in the block 170 to have invalid data and to prioritized relatively more unreliable data, in order to erase and reuse the block 170, garbage collection may be invoked and prioritized according to the temperature tracking table to allow the block 170 to be erased and released as a free block for subsequent write operations. The memory system 115 (e.g., by memory system controller 115) may first perform garbage collection for those partitions indicated by the temperature tracking table as having data written outside the nominal threshold, and thereafter perform garbage collection for partitions not indicated as having data written outside the nominal temperature range (e.g., partitions that are indicated as having been written within or inside the nominal temperature range). In some examples, some temperature ranges outside the nominal temperature range may be prioritized for garbage collection over other temperature ranges outside the nominal temperature range. For example partitions written with data in temperature ranges that are farthest from (e.g., relatively hotter than or colder than) the nominal temperature range may be queued for garbage collection before data written in other temperature ranges. Additionally or alternatively, data written in temperature range hotter than the nominal temperature range may be queued for garbage collection before data written in temperature ranges colder than the nominal temperature range, or vice versa.

The system 100 may include any quantity of non-transitory computer readable media that support temperature tracking for a memory system. For example, the host system 105, the memory system controller 115, or a memory device 130 may include or otherwise may access one or more non-transitory computer readable media storing instructions (e.g., firmware) for performing the functions ascribed herein to the host system 105, memory system controller 115, or memory device 130. For example, such instructions, if executed by the host system 105 (e.g., by the host system controller 106), by the memory system controller 115, or by a memory device 130 (e.g., by a local controller 135), may cause the host system 105, memory system controller 115, or memory device 130 to perform one or more associated functions as described herein.

FIG. 2 illustrates an example of a system 200 that supports temperature tracking for a memory system in accordance with examples as disclosed herein. The system 200 may be an example of a system 100 as described with reference to FIG. 1 or aspects thereof. The system 200 may include a memory system 210 configured to store data received from the host system 205 and to send data to the host system 205, if requested by the host system 205 using access commands (e.g., read commands or write commands). The system 200 may implement aspects of system 100 as described with reference to FIG. 1. For example, the memory system 210 and the host system 205 may be examples of the memory system 110 and the host system 105, respectively.

Memory system 210 may include memory devices 240 to store data transferred between memory system 210 and the host system 205, e.g., in response to receiving access commands from the host system 205, as described below. The memory devices 240 may include one or more memory devices as described with reference to FIG. 1. For example, the memory devices 240 may include NAND memory, PCM, self-selecting memory, 3D cross point, other chalcogenide-based memories, FERAM, MRAM, NOR (e.g., NOR flash) memory, STT-MRAM, CBRAM, RRAM, or OxRAM.

Memory system 210 may include a storage controller 230 for controlling the passing of data directly to and from the memory devices 240, e.g., for storing data, retrieving data, and determining memory locations in which to store data and from which to retrieve data. Storage controller 230 may communicate with memory devices 240 directly or via a bus (not shown) using a protocol specific to each type of memory device. In some cases, a single storage controller 230 may be used to control multiple memory devices of the same or different types. In some cases, memory system 210 may include multiple storage controllers 230, e.g., a different storage controller 230 for each type of memory device 240. In some cases, storage controller 230 may implement aspects of a local controller 135 as described with reference to FIG. 1.

The memory system 210 may additionally include an interface 220 for communication with the host system 205 and a buffer 225 for temporary storage of data being transferred between the host system 205 and the memory devices 240. The interface 220, buffer 225, and storage controller 230 may be for translating data between the host system 205 and the memory devices 240, e.g., as shown by a data path 250, and may be collectively referred to as data path components.

Using the buffer 225 to temporarily store data during transfers may allow data to be buffered as commands are being processed, thereby reducing latency between commands and allowing arbitrary data sizes associated with commands. This may also allow bursts of commands to be handled, and the buffered data may be stored or transmitted (or both) once a burst has stopped. The buffer 225 may include relatively fast memory (e.g., some types of volatile memory, such as SRAM or DRAM) or hardware accelerators or both to allow fast storage and retrieval of data to and from the buffer 225. The buffer 225 may include data path switching components for bi-directional data transfer between the buffer 225 and other components.

The temporary storage of data within a buffer 225 may refer to the storage of data in the buffer 225 during the execution of access commands. That is, upon completion of an access command, the associated data may no longer be maintained in the buffer 225 (e.g., may be overwritten with data for additional access commands). In addition, the buffer 225 may be a non-cache buffer. That is, data may not be read directly from the buffer 225 by the host system 205. For example, read commands may be added to a queue without an operation to match the address to addresses already in the buffer 225 (e.g., without a cache address match or lookup operation).

The memory system 210 may additionally include a memory system controller 215 for executing the commands received from the host system 205 and controlling the data path components in the moving of the data. The memory system controller 215 may be an example of the memory system controller 115 as described with reference to FIG. 1. A bus 235 may be used to communicate between the system components.

In some cases, one or more queues (e.g., a command queue 260, a buffer queue 265, and a storage queue 270) may be used to control the processing of the access commands and the movement of the corresponding data. This may be beneficial, e.g., if more than one access command from the host system 205 is processed concurrently by the memory system 210. The command queue 260, buffer queue 265, and storage queue 270 are depicted at the interface 220, memory system controller 215, and storage controller 230, respectively, as examples of a possible implementation. However, queues, if used, may be positioned anywhere within the memory system 210.

Data transferred between the host system 205 and the memory devices 240 may take a different path in the memory system 210 than non-data information (e.g., commands, status information). For example, the system components in the memory system 210 may communicate with each other using a bus 235, while the data may use the data path 250 through the data path components instead of the bus 235. The memory system controller 215 may control how and if data is transferred between the host system 205 and the memory devices 240 by communicating with the data path components over the bus 235 (e.g., using a protocol specific to the memory system 210).

If a host system 205 transmits access commands to the memory system 210, the commands may be received by the interface 220, e.g., according to a protocol (e.g., a UFS protocol or an eMMC protocol). Thus, the interface 220 may be considered a front end of the memory system 210. Upon receipt of each access command, the interface 220 may communicate the command to the memory system controller 215, e.g., via the bus 235. In some cases, each command may be added to a command queue 260 by the interface 220 to communicate the command to the memory system controller 215.

The memory system controller 215 may determine that an access command has been received based on the communication from the interface 220. In some cases, the memory system controller 215 may determine the access command has been received by retrieving the command from the command queue 260. The command may be removed from the command queue 260 after it has been retrieved therefrom, e.g., by the memory system controller 215. In some cases, the memory system controller 215 may cause the interface 220, e.g., via the bus 235, to remove the command from the command queue 260.

Upon the determination that an access command has been received, the memory system controller 215 may execute the access command. For a read command, this may mean obtaining data from the memory devices 240 and transmitting the data to the host system 205. For a write command, this may mean receiving data from the host system 205 and moving the data to the memory devices 240.

In either case, the memory system controller 215 may use the buffer 225 for, among other things, temporary storage of the data being received from or sent to the host system 205. The buffer 225 may be considered a middle end of the memory system 210. In some cases, buffer address management (e.g., pointers to address locations in the buffer 225) may be performed by hardware (e.g., dedicated circuits) in the interface 220, buffer 225, or storage controller 230.

To process a write command received from the host system 205, the memory system controller 215 may first determine if the buffer 225 has sufficient available space to store the data associated with the command. For example, the memory system controller 215 may determine, e.g., via firmware (e.g., controller firmware), an amount of space within the buffer 225 that may be available to store data associated with the write command.

In some cases, a buffer queue 265 may be used to control a flow of commands associated with data stored in the buffer 225, including write commands. The buffer queue 265 may include the access commands associated with data currently stored in the buffer 225. In some cases, the commands in the command queue 260 may be moved to the buffer queue 265 by the memory system controller 215 and may remain in the buffer queue 265 while the associated data is stored in the buffer 225. In some cases, each command in the buffer queue 265 may be associated with an address at the buffer 225. That is, pointers may be maintained that indicate where in the buffer 225 the data associated with each command is stored. Using the buffer queue 265, multiple access commands may be received sequentially from the host system 205 and at least portions of the access commands may be processed concurrently.

If the buffer 225 has sufficient space to store the write data, the memory system controller 215 may cause the interface 220 to transmit an indication of availability to the host system 205 (e.g., a “ready to transfer” indication), e.g., according to a protocol (e.g., a UFS protocol or an eMMC protocol). As the interface 220 subsequently receives from the host system 205 the data associated with the write command, the interface 220 may transfer the data to the buffer 225 for temporary storage using the data path 250. In some cases, the interface 220 may obtain from the buffer 225 or buffer queue 265 the location within the buffer 225 to store the data. The interface 220 may indicate to the memory system controller 215, e.g., via the bus 235, if the data transfer to the buffer 225 has been completed.

Once the write data has been stored in the buffer 225 by the interface 220, the data may be transferred out of the buffer 225 and stored in a memory device 240. This may be done using the storage controller 230. For example, the memory system controller 215 may cause the storage controller 230 to retrieve the data out of the buffer 225 using the data path 250 and transfer the data to a memory device 240. The storage controller 230 may be considered a back end of the memory system 210. The storage controller 230 may indicate to the memory system controller 215, e.g., via the bus 235, that the data transfer to a memory device of the memory devices 240 has been completed.

In some cases, a storage queue 270 may be used to aid with the transfer of write data. For example, the memory system controller 215 may push (e.g., via the bus 235) write commands from the buffer queue 265 to the storage queue 270 for processing. The storage queue 270 may include entries for each access command. In some examples, the storage queue 270 may additionally include a buffer pointer (e.g., an address) that may indicate where in the buffer 225 the data associated with the command is stored and a storage pointer (e.g., an address) that may indicate the location in the memory devices 240 associated with the data. In some cases, the storage controller 230 may obtain from the buffer 225, buffer queue 265, or storage queue 270 the location within the buffer 225 from which to obtain the data. The storage controller 230 may manage the locations within the memory devices 240 to store the data (e.g., performing wear-leveling, garbage collection, and the like). The entries may be added to the storage queue 270, e.g., by the memory system controller 215. The entries may be removed from the storage queue 270, e.g., by the storage controller 230 or memory system controller 215 upon completion of the transfer of the data.

To process a read command received from the host system 205, the memory system controller 215 may again first determine if the buffer 225 has sufficient available space to store the data associated with the command. For example, the memory system controller 215 may determine, e.g., via firmware (e.g., controller firmware), an amount of space within the buffer 225 that may be available to store data associated with the read command.

In some cases, the buffer queue 265 may be used to aid with buffer storage of data associated with read commands in a similar manner as discussed above with respect to write commands. For example, if the buffer 225 has sufficient space to store the read data, the memory system controller 215 may cause the storage controller 230 to retrieve the data associated with the read command from a memory device 240 and store the data in the buffer 225 for temporary storage using the data path 250. The storage controller 230 may indicate to the memory system controller 215, e.g., via the bus 235, once the data transfer to the buffer 225 has been completed.

In some cases, the storage queue 270 may be used to aid with the transfer of read data. For example, the memory system controller 215 may push the read command to the storage queue 270 for processing. In some cases, the storage controller 230 may obtain from the buffer 225 or storage queue 270 the location within the memory devices 240 from which to retrieve the data. In some cases, the storage controller 230 may obtain from the buffer queue 265 the location within the buffer 225 to store the data. In some cases, the storage controller 230 may obtain from the storage queue 270 the location within the buffer 225 to store the data. In some cases, the memory system controller 215 may move the command processed by the storage queue 270 back to the command queue 260.

Once the data has been stored in the buffer 225 by the storage controller 230, the data may be transferred out of the buffer 225 and sent to the host system 205. For example, the memory system controller 215 may cause the interface 220 to retrieve the data out of the buffer 225 using the data path 250 and transmit the data to the host system 205, e.g., according to a protocol (e.g., a UFS protocol or an eMMC protocol). For example, the interface 220 may process the command from the command queue 260 and may indicate to the memory system controller 215, e.g., via the bus 235, that the data transmission to the host system 205 has been completed.

The memory system controller 215 may execute received commands according to an order (e.g., a first-in, first-out order, according to the order of the command queue 260). For each command, the memory system controller 215 may cause data corresponding to the command to be moved into and out of the buffer 225, as discussed above. As the data is moved into and stored within the buffer 225, the command may remain in the buffer queue 265. A command may be removed from the buffer queue 265, e.g., by the memory system controller 215, if the processing of the command has been completed (e.g., if data corresponding to the access command has been transferred out of the buffer 225). If a command is removed from the buffer queue 265, the address previously storing the data associated with that command may be available to store data associated with a new command.

The memory system controller 215 may additionally be configured for operations associated with the memory devices 240. For example, the memory system controller 215 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., LBAs) associated with commands from the host system 205 and physical addresses (e.g., physical block addresses) associated with memory cells within the memory devices 240. That is, the host system 205 may issue commands indicating one or more LBAs and the memory system controller 215 may identify one or more physical block addresses indicated by the LBAs. In some cases, one or more contiguous LBAs may correspond to noncontiguous physical block addresses. In some cases, the storage controller 230 may be configured to perform one or more of the above operations in conjunction with or instead of the memory system controller 215. In some cases, the memory system controller 215 may perform the functions of the storage controller 230 and the storage controller 230 may be omitted.

The memory system 210 may support a temperature tracking mechanism for one or more memory devices 240 to support temperature compensations on read operations. For example, the storage controller 230, a memory device 240, or both, may include a temperature sensor 275. In some cases, the storage controller 230 may include a temperature sensor 275-a and one or more memory devices 240 may include respective temperature sensors 275-b (e.g., at one or more NAND dies, as described with reference to FIG. 1). The temperature sensors 275 may perform temperature readings for the memory system 210 or a specific memory device 240. In some examples, a temperature sensor 275 may be triggered to perform a temperature reading with each write command to one or more of the partitions of the one or more memory devices 240. Additionally or alternatively, a temperature sensor 275 may periodically or aperiodically perform temperature readings (e.g., based on a timer or a counter). In some examples, the memory system 210 (e.g., the storage controller 230) may determine multiple temperature readings for a specific timestamp or operation (e.g., write operation) and may determine a current temperature value based on the multiple temperature readings. For example, both a temperature sensor 275-a and a temperature sensor 275-b may detect temperature readings. The memory system 210 may average the temperature readings, select a “most accurate” temperature reading, select a “worst case” temperature reading (e.g., a temperature reading corresponding to a greatest temperature compensation factor or a highest temperature from a group or a lowest temperature for a group), or perform some other operation to determine the current temperature.

The memory system 210 may additionally store a set of temperature ranges (e.g., at the memory system controller 215, the storage controller 230, or one or more memory devices 240), where each of the one or more partitions of the one or memory devices 240 may have corresponding temperature ranges of the set of temperature ranges. In some examples, the partitions of the one or memory devices 240 has corresponding temperature ranges of the set of temperature ranges. In some examples, the one or more partitions may be or include blocks or virtual blocks, either or both of which may be examples of a set of blocks 170 described with reference to FIG. 1. In some cases, if data is written to a partition of memory device 240 when the device temperature is within a range of the set of temperature ranges, the memory system 210 may implement different handling (which may be referred to as special handling) on one or more read operations to account for the temperature at write time. The temperature ranges may be based on the characterizations for the memory devices 240. For example, different temperature ranges may correspond to different temperature compensation values for reading data from a memory device 240 (e.g., based on one or more aspects of the memory device 240). In some example, the temperature ranges and corresponding temperature compensation values may be stored, for example, in a temperature tracking table. In some examples, the entries for the temperature tracking table may be created and updated in volatile memory (e.g., in a cache at a controller, such as a storage controller), while the temperature tracking table may be stored (e.g., stored persistently) in a memory device (e.g., in SLCs). A temperature tracking table may be one example of a set of temperature ranges and corresponding sets of partitions. However, the memory system 210 may implement alternative or additional data structures to track temperature data for partitions of the memory system 210.

In some cases, the memory system 210 may store a set of temperature ranges of a given size. For example, the memory system 210 may store temperature ranges spanning five degrees Celsius (° C.) between −25° C. and 85° C. In other cases, the memory system 210 may store temperature ranges spanning different sizes of temperature ranges. For example, the memory system 210 may store a “nominal” temperature range and one or more temperature ranges outside the nominal temperature range (e.g., “extreme” temperature ranges that are above or below the nominal temperature range) of different sizes. The nominal temperature range may correspond to no temperature compensation or minimal temperature compensation for reading data, while each extreme temperature range may correspond to a respective temperature compensation value for reading data. For example, the nominal temperature range may span from 0° C. to 65° C. for a memory device 240 in a smartphone, 0° C. to 100° C. for a memory device 240 in a vehicle, or another supported temperature range. The extreme temperature ranges may be more granular, and extreme temperature ranges farther from the nominal temperature range may correspond to more significant temperature compensation values. The set of temperature ranges may be pre-defined for a memory system 210 or memory device 240, or may be dynamically determined (e.g., based on one or more determinations or measurements by one or more components in real time or based on usage).

The memory system 210 may populate the set of temperature ranges and corresponding set of partitions (e.g., a temperature tracking table) with temperature data so that unreliable data may be identified and one or mitigation procedures may be performed for the data. For example, if the memory system 210 is writing data to a memory device 240, the memory system 210, memory device 240, or storage controller 230 (or any combination thereof) may identify the partition to which the data is to be written and determine a temperature based on reading a temperature sensor 275. The memory system 210, memory device 240, or storage controller 230 may then write or may initiate writing the data to the partition and record an indication (e.g., by writing a bit) in the temperature tracking table at an entry corresponding to the partition and a temperature range in which the temperature falls. If an indication for the same partition and temperature already exists in the temperature tracking table, the indication may be maintained (e.g., maintain the same bit value) rather than a new indication recorded (e.g., a new bit value written). Each time data is written to the partition, an indication corresponding to the temperature reading at the time the data is written may be stored, such as by being recorded (e.g., a new indication or an indication being maintained), in the temperature tracking table. The storage controller 230 may periodically or aperiodically copy the temperature tracking table and associated entries in persistent memory (e.g., in a memory device 240). For example, the data may be persisted in NAND-based QLCs, while the temperature tracking table may be persisted in NAND-based SLCs.

The memory system 210 may use the temperature data recorded in the set of temperature ranges and corresponding set of partitions (e.g., a temperature tracking table) to identify unreliable data and perform one or mitigation procedures for the data. For example, if the memory system 210 is reading data from a memory device 240, the memory system 210, memory device 240, or storage controller 230 may identify the partition from which the data is to be read. The memory system 210 may then read temperature data associated with the partition from the temperature tracking table, where the temperature data indicates, for the partition (e.g., a subset of the memory device 240), temperature ranges in which data of the partition was written. If the temperature data indicates that all the data in the partition was written to the partition inside or within a temperature threshold (e.g., in a nominal temperature range), then the memory system 210, memory device 240, or storage controller 230 may determine to skip performing a temperature compensation procedure. However, if the temperature data indicates that some or all of the data in the partition was written to the partition outside the temperature threshold (e.g., outside the nominal temperature range), then the memory system 210, memory device 240, or storage controller 230 may determine to perform a temperature compensation procedure for the data. In some cases, metadata indicating the temperature at which or the temperature range in which the data was written may be stored along with the associated data. The metadata may be read for the data, and a temperature compensation procedure performed according to the temperature indicated by the metadata.

In some examples, the memory system 210, memory device 240, or storage controller 230 may perform selective relocation of data written to a partition while the temperature is outside the temperature threshold, or perform a garbage collection procedure that prioritizes partitions based on temperature data, or both. Applying the temperature compensation procedure, selective relocation, and prioritized garbage collection, or a combination of these, may mitigate the negative effects of temperature on data retention and reading accuracy, effectively reducing the bit-error rate associated with read operations.

FIG. 3 illustrates an example of a process flow 300 that supports temperature tracking for a memory system in accordance with examples as disclosed herein. The process flow 300 a may be performed by a memory system or a component thereof, as described with reference to FIGS. 1 and 2. For example, a controller coupled with a memory array (e.g., an example or component of the memory system 110 or 210, such as memory system controller 115, a local controller 135, memory system controller 215, or storage controller 230) may perform one or more functions described herein. Alternative examples of the following may be implemented, where some steps are performed in a different order than described or are not performed at all. In some cases, steps may include additional features not mentioned below, or further steps may be added. The memory system may include memory cells that are affected by temperature variations, for example MLCs, such as TLCs or QLCs, though the techniques described herein may apply to other memory cell types.

At 305, a set of temperature ranges (e.g., one or more temperature ranges) and a set of partitions (e.g., a set of one or more partitions) of a memory system may be stored. Each temperature range of the set of temperature ranges may map to one or more respective partitions of the set of partitions. In one example, the set of temperature ranges and set of partitions may represent a temperature tracking table. Initially, the temperature tracking table may be empty, and have no set bits, for example at or immediately following memory system initialization, among other examples. In some examples, the entries for the temperature tracking table may be created and updated in volatile memory (e.g., in a cache at a controller, such as a storage controller), while the temperature tracking table may be persisted in a non-volatile memory device (e.g., in NAND-based SLCs).

At 310, the set of temperature ranges and set of partitions (e.g., a temperature tracking table) may be populated in a location with temperature data corresponding to data written to a memory device in response to received write commands. In some examples, populating the location with the set of temperature ranges and set of partitions may be performed in response to received write commands and may be performed for each write command received.

At 315, a write command may be received. For example, a memory system may receive the write command from a host system. The write command may indicate data to write to a memory device (e.g., a NAND-based memory storage cell). The NAND storage may be programmed in a page-sequential order across one or more grouped blocks. Each grouped block may be referred to as a virtual block (e.g., virtual block 0 may correspond to block 0 on all planes and NAND dies in a memory device). Within a virtual block, each potential storage location of a host logical block addressed by a host LBA may be referred to as a virtual page. The virtual pages can be counted sequentially beginning at 0 at the start of a virtual block and incrementing in programming order. The position that is next-to-be-programmed in a virtual block may be called a cursor. In some cases, one or more virtual pages, one or more virtual blocks, or a combination thereof may be referred to as a partition.

At 320, the data may be written to a partition based on the write command. For example, a controller (e.g., a storage controller) may cause the data to be stored in a partition of the memory device starting at the cursor position. The controller, memory device, memory system, or some combination thereof, may determine a temperature (e.g., a current temperature) at which the data is written to the partition. The temperature reading for the memory device may fall within a temperature range of a set of pre-defined temperature ranges associated with that partition.

At 325, an indication of the temperature range into which the temperature reading falls may be written. In some examples, the controller may write or initiating the writing of the indication of the temperature range. In the example where a single bit of the temperature tracking table is used for each temperature range associated with a single partition, the controller may write temperature data in the table that corresponds to that temperature range for the partition to indicate that data has been written to that partition with a temperature that falls within that temperature range. For example, the temperature data may be a first bit value (e.g., a “1”). In an example where no temperature data has previously been written to the table (e.g., after the table has been cleared of temperature data), the temperature data being written may introduce a change in the table from a second bit value (e.g., a “0”) to the first bit value. In an example, where data has previously been written to the partition at a temperature that falls within that temperature range, the temperature data being written may not introduce a change in the table. In other examples, a specific temperature that falls within a given temperature range may be stored as the temperature data for each instance.

At 330, a read command may be received. For example, a memory system may receive the read command from a host system. The read command may indicate data to read from a memory device (e.g., a NAND-based memory storage cell). For example, the read command may indicate a host LBA corresponding to the data.

At 335, a partition may be identified. For example, a controller (e.g., a storage controller) may translate the host LBA indicated by the read command to a physical address in the memory device (e.g., using an L2P mapping table). The physical address may correspond to a virtual block and virtual page of the memory device. In some cases, the one or more virtual blocks, one or more virtual pages, or combination thereof, to read may correspond to the partition.

At 340, the controller may determine if the data to be read was written to the partition outside a threshold temperature. For example, the controller may read the temperature tracking table for entries corresponding to the partition from which the data is to be read. The temperature tracking table may indicate that the partition has been written with data inside (e.g., within) the threshold temperature, for example by the controller reading bits from the temperature tracking table corresponding to one or more nominal temperature ranges for the partition. The temperature tracking table may additionally or alternatively indicate that the partition has been written with data outside the threshold temperature, for example in one or more extreme temperature ranges (e.g., a lower or higher temperature range compared to the one or more nominal ranges or one or more threshold temperatures), for example by the controller reading bits from the temperature tracking table corresponding to such extreme temperature ranges for the partition. In some examples, the temperature tracking table may indicate that data has been written to the partition in any combination of temperature ranges, some of which may be inside (e.g., within) the temperature threshold (e.g., be nominal temperature ranges) and some of which may be outside the temperature threshold (e.g., be extreme temperature ranges). In some cases, where the data to be read is from multiple partitions, one partition may include data that was written inside the temperature threshold and a second partition may include at least some data that was written in outside the temperature threshold.

If the partition from which the data is to be read was written with data at a temperature outside the temperature threshold, at 345, the controller may read the data from the partition using a temperature compensation procedure. For example, the temperature tracking table may indicate, for one or more given partitions, that at least some data was written to the partition while a temperature reading (e.g., from one or more temperature sensors, or a combination of temperature sensors) indicated a temperature outside the temperature threshold (e.g., in one or more of the extreme temperature ranges). In some examples, the temperature tracking table may indicate that at least some data was written to the partition inside or within the temperature threshold, and at least some data was written to the partition outside the temperature threshold. In response to the partition having been written with at least some data outside the temperature threshold, the controller may perform a temperature compensation procedure on the data to be read from the partition. In some examples, temperature compensation for a partition may include adjusting one or more voltages (e.g., threshold voltages) used for at least a portion of memory devices of a partition (e.g., adjusting a voltage of a digit (bit) line or a word line of the memory cells of the partition) based on a temperature compensation value (e.g., a temperature coefficient) associated with the temperature at which a partition was written during a read process for the partition. In some examples, different temperature ranges associated with the partition may be associated with different temperature compensation values applied during temperature compensation of the read process.

If the partition from which the data is to be read was written with data at a temperature inside (e.g., within) the temperature threshold, at 350, the controller may skip a temperature compensation procedure for the data to be read from the partition. In some examples, the temperature compensation procedure may be skipped or otherwise omitted where the temperature data corresponding to the partition from the temperature tracking table indicates that no data was written to the partition outside the temperature threshold (e.g., no bits of the table indicate that data was written to the partition while the temperature was in an extreme temperature range). For example, the temperature data corresponding to the partition from the temperature tracking table only has bits that indicate writes to the partition inside or within the temperature threshold (e.g., bits of the table only indicate writes within nominal temperature ranges). Skipping the temperature compensation procedure as part of a read may reduce read latency, for example for memory systems that operate in high cross temperature environments.

In some cases, at 355, selective relocation of data may be performed for data written outside the temperature threshold. For example, a controller (e.g., a storage controller) may determine from the temperature tracking table that at least some data was written to the partition outside a threshold temperature. Temperature metadata may be stored in the partition along with data. The controller may then read such metadata and relocate (e.g., write to a new location in the memory system) the corresponding data. In some examples, following the selective relocation procedure for the partition, the controller may erase bits of the temperature tracking table associated with the partition (e.g., “clear” the temperature tracking table for the partition). Performing selective data relocation may mitigate or avoid data retention issues caused by writing data at temperatures outside a nominal temperature range.

In some cases, the selective relocation may be performed after determining that the memory system is operating inside the temperature threshold (e.g., the nominal temperature range), or inside a second temperature threshold within the temperature threshold (e.g., a narrower temperature threshold within a sub-range of the nominal temperature range). In some example, the controller may determine that a temperature reading indicates that the memory system has been inside the second (e.g., narrower) temperature threshold for at least a threshold amount of time, and then perform the selective relocation procedure in response to the determination.

In some cases, at 360, garbage collection procedure may be performed based on temperature information. For example, a controller (e.g., a storage controller) may perform a garbage collection procedure that prioritizes one or more operations related to one or more partitions based on temperature data. The controller may scan the temperature tracking table to determine partitions having data outside a threshold temperature (e.g., at a temperature or in a temperature range above or below a nominal temperature range or above or below a temperature threshold), and rewrite the data of the partition to another location of the memory device, for example a different partition. Based on this garbage collection procedure, the controller may erase (e.g., “clear”) the entries of the temperature tracking table for the partition and may do so opportunistically (e.g., when controller or the memory device is not otherwise in use or in a state of reduced bandwidth requirements or constraints, during a period in which other commands or operations cannot be executed or performed). Such garbage collection procedure may reduce the overall amount of data written to the memory device at temperatures outside the threshold temperature (e.g., at extreme temperatures) and may do so more efficiently and effectively based on the temperature data than other techniques.

In some cases, the garbage collection procedure may be performed after determining that the memory system is operating inside the temperature threshold (e.g., the nominal temperature range), or inside a second temperature threshold within the temperature threshold (e.g., a narrower temperature threshold within a sub-range of the nominal temperature range). In some example, the controller may determine that a temperature reading indicates that the memory system has been inside the second (e.g., narrower) temperature threshold for at least a threshold amount of time, and then perform the garbage collection procedure in response to the determination.

FIG. 4 illustrates an example of a storage configuration 400 that supports temperature tracking for a memory system in accordance with examples as disclosed herein.

The storage configuration 400 may be supported by a memory system, memory device, controller, or some combination thereof as described with reference to FIGS. 1, 2, and 3. For example, entries for the temperature tracking table 405 may be created and updated in volatile memory (e.g., in a cache at a controller, such as a storage controller), while the temperature tracking table 405 may be persisted in a memory device (e.g., in SLCs). The set of temperature ranges 410 and corresponding sets of partitions 415 may defined for a memory system or memory device and may be stored at the memory system or memory device.

The temperature tracking table 405 may be one example of a set of temperature ranges 410 and corresponding sets of partitions 415. However, it is to be understood that a memory system may implement additional or alternative data structures to track temperature data for partitions (e.g., blocks or virtual blocks) of the memory system within different temperature ranges (e.g., inside a nominal temperature range or outside the nominal temperature range). Additionally, while temperature tracking table 405 illustrates seven temperature ranges 410 (temperature ranges 410-a, 410-b, 410-c, 410-d, 410-e, 410-f, and 410-g), it is to be understood that any quantity and size of temperature ranges 410 may be supported. Similarly, although temperature tracking table 405 illustrates eight partitions 415 (partitions 415-a, 415-b, 415-c, 415-d, 415-e, 415-f, 415-g, and 415-h), it is to be understood that any quantity or type of partition 415 may be supported. Temperature ranges 410 may be of any same size, different sizes, a mix of various (e.g., irregular) sizes, and may be of different size, or different quantity, or both, for different partitions 415. In some examples, the temperature tracking table 405 may be created and modified in volatile memory, and stored in persistent storage (e.g., non-volatile memory). Such storage of the temperature tracking table 405 may occur periodically, aperiodically, or if the temperature tracking table 405 is written to or otherwise modified, among other conditions.

In one example of a temperature tracking table, there may be a single bit per temperature range 410, and eight or fewer temperature ranges 410 per partition. One byte of the bit may then represent temperature data for per partition. One byte per partition may provide for efficient reading against the temperature tracking table. One example of a memory system may include 1,024 partitions (e.g., 1,024 virtual blocks), such that the temperature tracking table may be stored (e.g., persistently) in 1 kilobyte. In one example, 1 kilobyte of SRAM may be used to store the temperature data of the temperature tracking table during operation of the memory system, while 1 kilobyte of NAND memory may be used to store the temperature data of the temperature tracking table if the memory system is powered off.

In one example of the temperature tracking table, more than one bit per temperature range 410 and partition 415 entry may be used. For example, one or more additional bits may be used to store information indicating an order (e.g., a priority) for performing garbage collection or a quantity of temperature determinations for a respective temperature range (e.g., tracking a quantity of temperature measurements that have been made and returned in a given range over a duration and using a counter to track the quantity).

The garbage collection may be performed on a prioritized (e.g., dynamic) basis. In some examples, then garbage collection may be performed for the respective partition with the highest quantity of noted temperature measurements in a range above a nominal temperature. For example, garbage collection may be performed first for the partition corresponding to the highest quantity of temperature measurements in range 410-g (e.g., Partition7) and then for the partition corresponding to the second highest quantity of temperature measurements in range 410-g (e.g., Partition0).

Additionally or alternatively, garbage collection may be performed for the partition corresponding to the highest quantity of temperature measurements in a group or multiple ranges, for example, that may be most at risk in being outside a nominal range or above a threshold, such as the group of ranges 410-g and 410-f and Partition® (even if this respective partition did not have the highest quantity of temperature measurements in the highest range, such as 410-g.

Additionally or alternatively, the examples discussed herein may also apply to the lower temperatures (e.g., garbage collection may be performed for the partition or partitions corresponding to the highest quantity of temperature measurements in one or more ranges that may be most at risk in being outside a nominal range (e.g., below a nominal range) or below a threshold. In some examples, garbage collection may be performed for the respective partition with the highest quantity of noted temperature measurements in a range below a nominal temperature. For example, garbage collection may be performed first for the partition corresponding to the highest quantity of temperature measurements in range 410-a (e.g., Partition6) and then for the partition corresponding to the second highest quantity of temperature measurements in range 410-a (e.g., Partition1).

Additionally or alternatively, garbage collection may be performed for the partition corresponding to the highest quantity of temperature measurements in a group or multiple ranges, for example, that may be most at risk in being outside a nominal range or below a threshold, such as the group of ranges 410-a and 410-b and Partition1 (even if this respective partition did not have the highest quantity of temperature measurements in the highest range, such as 410-a.

Following garbage collection for a partition (or multiple partitions), the entries of the temperature tracking table may be updated (e.g., erased, cleared, set to a default value). For example, the set of entries 420-a of the temperature tracking table for partition 415-e may indicate that data was written to partition 415-e in temperature ranges 415-c and 415-e prior to garbage collection. Following garbage collection, the set of entries 420-b of the temperature tracking table for partition 415-e may be erased, such that no temperature data indicates that data was written to partition 415-e in any of temperature ranges 415.

FIG. 5 shows a block diagram 500 of a memory system 520 that supports temperature tracking for a memory system in accordance with examples as disclosed herein. The memory system 520 may be an example of aspects of a memory system as described with reference to FIGS. 1 through 4. The memory system 520, or various components thereof, may be an example of means for performing various aspects of temperature tracking for a memory system as described herein. For example, the memory system 520 may include a temperature tracking component 525, a command component 530, a temperature detector 535, a read component 540, a garbage collection component 545, a write component 550, or any combination thereof. Each of these components may communicate, directly or indirectly, with one another (e.g., via one or more buses).

The temperature tracking component 525 may be configured as or otherwise support a means for storing a set of temperature ranges and a set of partitions of a memory system, where each temperature range of the set of temperature ranges maps to one or more respective partitions of the set of partitions. The command component 530 may be configured as or otherwise support a means for receiving a command to read a partition of the set of partitions. The temperature detector 535 may be configured as or otherwise support a means for determining whether temperature data associated with the set of temperature ranges for the partition indicates that data was written to the partition outside a threshold temperature. The read component 540 may be configured as or otherwise support a means for reading data from the partition based at least in part on the determining whether the temperature data associated with the set of temperature ranges indicates that the data was written to the partition outside of the threshold temperature.

In some examples, the garbage collection component 545 may be configured as or otherwise support a means for performing a garbage collection procedure on a first one or more partitions of the set of partitions before performing the garbage collection procedure on a second one or more partitions of the set of partitions based at least in part on determining that the first one or more partitions include data written at a temperature outside the threshold temperature and determining that the second one or more partitions include data written at a temperature within the threshold temperature.

In some examples, the write component 550 may be configured as or otherwise support a means for writing data to the partition. In some examples, the temperature tracking component 525 may be configured as or otherwise support a means for writing an indication of a temperature range of the set of temperature ranges that corresponds to a temperature of the memory system that is associated with writing the data to the partition, where the temperature data for the partition includes the indication of the temperature range that corresponds to the temperature.

In some examples, to support reading the data from the partition, the read component 540 may be configured as or otherwise support a means for performing a temperature compensation procedure on the data based at least in part on determining that the temperature data for the partition indicates that the data was written to the partition outside the threshold temperature, the temperature compensation procedure including adjusting one or more aspects of the data based at least in part on a temperature range of the set of temperature ranges in which the data was written at the memory system.

In some examples, to support reading the data from the partition, the read component 540 may be configured as or otherwise support a means for refraining from performing a temperature compensation procedure for the data based at least in part on determining that the temperature data for the partition indicates that the data was written to the partition inside the threshold temperature.

In some examples, to support determining the set of temperature ranges and the set of partitions, the temperature tracking component 525 may be configured as or otherwise support a means for partitioning the memory system into the set of partitions. In some examples, to support determining the set of temperature ranges and the set of partitions, the temperature tracking component 525 may be configured as or otherwise support a means for setting the set of temperatures ranges corresponding to the set of partitions of the partitioned memory system.

In some examples, the temperature tracking component 525 may be configured as or otherwise support a means for determining a table of the set of temperature ranges mapped to the set of partitions, where determining whether the temperature data associated with the set of temperature ranges for the partition indicates that the data was written to the partition outside the threshold temperature includes reading one or more entries of the table and corresponding to the partition.

In some examples, the temperature data is stored in a first portion of the memory system different than a second portion of the memory system that stores the data. In some examples, the first portion of the memory system includes memory cells having a first number of one or more levels, and the second portion of the memory system includes memory cells having a second number of levels greater than the first number of one or more levels. In some examples, the memory cells having the first number of one or more levels include SLCs, and the memory cells having the second number of levels include QLCs.

In some examples, the write component 550 may be configured as or otherwise support a means for updating the partition. In some examples, the temperature tracking component 525 may be configured as or otherwise support a means for updating the temperature data associated with the partition before writing new data to the partition.

In some examples, the memory system includes one or more non-volatile memory devices. In some examples, the memory device includes one or more not- and memory devices.

FIG. 6 shows a flowchart illustrating a method 600 that supports temperature tracking for a memory system in accordance with examples as disclosed herein. The operations of method 600 may be implemented by a memory system or its components as described herein. For example, the operations of method 600 may be performed by a memory system as described with reference to FIGS. 1 through 5. In some examples, a memory system may execute a set of instructions to control the functional elements of the device to perform the described functions. Additionally or alternatively, the memory system may perform aspects of the described functions using special-purpose hardware.

At 605, the method may include storing a set of temperature ranges and a set of partitions of a memory system, where each temperature range of the set of temperature ranges maps to one or more respective partitions of the set of partitions. The operations of 605 may be performed in accordance with examples as disclosed herein. In some examples, aspects of the operations of 605 may be performed by a temperature tracking component 525 as described with reference to FIG. 5.

At 610, the method may include receiving a command to read a partition of the set of partitions. The operations of 610 may be performed in accordance with examples as disclosed herein. In some examples, aspects of the operations of 610 may be performed by a command component 530 as described with reference to FIG. 5.

At 615, the method may include determining whether temperature data associated with the set of temperature ranges for the partition indicates that data was written to the partition outside a threshold temperature. The operations of 615 may be performed in accordance with examples as disclosed herein. In some examples, aspects of the operations of 615 may be performed by a temperature detector 535 as described with reference to FIG. 5.

At 620, the method may include reading data from the partition based at least in part on the determining whether the temperature data associated with the set of temperature ranges indicates that the data was written to the partition outside of the threshold temperature. The operations of 620 may be performed in accordance with examples as disclosed herein. In some examples, aspects of the operations of 620 may be performed by a read component 540 as described with reference to FIG. 5.

In some examples, an apparatus as described herein may perform a method or methods, such as the method 600. The apparatus may include, features, circuitry, logic, means, or instructions (e.g., a non-transitory computer-readable medium storing instructions executable by a processor) for storing a set of temperature ranges and a set of partitions of a memory system, where each temperature range of the set of temperature ranges maps to one or more respective partitions of the set of partitions, receiving a command to read a partition of the set of partitions, determining whether temperature data associated with the set of temperature ranges for the partition indicates that data was written to the partition outside a threshold temperature, and reading data from the partition based at least in part on the determining whether the temperature data associated with the set of temperature ranges indicates that the data was written to the partition outside of the threshold temperature.

Some examples of the method 600 and the apparatus described herein may further include operations, features, circuitry, logic, means, or instructions for performing a garbage collection procedure on a first one or more partitions of the set of partitions before performing the garbage collection procedure on a second one or more partitions of the set of partitions based at least in part on determining that the first one or more partitions include data written at a temperature outside the threshold temperature and determining that the second one or more partitions include data written at a temperature within the threshold temperature.

Some examples of the method 600 and the apparatus described herein may further include operations, features, circuitry, logic, means, or instructions for writing data to the partition and writing an indication of a temperature range of the set of temperature ranges that corresponds to a temperature of the memory system that may be associated with writing the data to the partition, where the temperature data for the partition includes the indication of the temperature range that corresponds to the temperature.

In some examples of the method 600 and the apparatus described herein, reading the data from the partition may include operations, features, circuitry, logic, means, or instructions for performing a temperature compensation procedure on the data based at least in part on determining that the temperature data for the partition indicates that the data was written to the partition outside the threshold temperature, the temperature compensation procedure including adjusting one or more aspects of the data based at least in part on a temperature range of the set of temperature ranges in which the data was written at the memory system.

In some examples of the method 600 and the apparatus described herein, reading the data from the partition may include operations, features, circuitry, logic, means, or instructions for refraining from performing a temperature compensation procedure for the data based at least in part on determining that the temperature data for the partition indicates that the data was written to the partition inside the threshold temperature.

In some examples of the method 600 and the apparatus described herein, determining the set of temperature ranges and the set of partitions may include operations, features, circuitry, logic, means, or instructions for partitioning the memory system into the set of partitions and setting the set of temperatures ranges corresponding to the set of partitions of the partitioned memory system.

Some examples of the method 600 and the apparatus described herein may further include operations, features, circuitry, logic, means, or instructions for determining a table of the set of temperature ranges mapped to the set of partitions, where determining whether the temperature data associated with the set of temperature ranges for the partition indicates that the data was written to the partition outside the threshold temperature includes reading one or more entries of the table and corresponding to the partition.

In some examples of the method 600 and the apparatus described herein, the temperature data may be stored in a first portion of the memory system different than a second portion of the memory system that stores the data. In some examples of the method 600 and the apparatus described herein, the first portion of the memory system includes memory cells having a first number of one or more levels, and the second portion of the memory system includes memory cells having a second number of levels greater than the first number of one or more levels. In some examples of the method 600 and the apparatus described herein, the memory cells having the first number of one or more levels include single-level cells, and the memory cells having the second number of levels include quad-level cells.

Some examples of the method 600 and the apparatus described herein may further include operations, features, circuitry, logic, means, or instructions for updating the partition and updating the temperature data associated with the partition before writing new data to the partition.

In some examples of the method 600 and the apparatus described herein, the memory system includes one or more non-volatile memory devices. In some examples of the method 600 and the apparatus described herein, the memory device includes one or more not- and memory devices.

It should be noted that the methods described above describe possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

If used to describe a conditional action or process, the terms “if,” “when,” “based on,” “based at least in part on,” and “in response to,” may be interchangeable.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” refers to condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as a n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to providing an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over as one or more instructions or code on a computer-readable medium. Other examples and implementations are within the scope of the disclosure and appended claims. For example, due to the nature of software, functions described above can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and modules described in connection with the disclosure herein may be implemented or performed with a general-purpose processor, a DSP, an ASIC, an FPGA or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, digital subscriber line (DSL), or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. An apparatus, comprising:
a memory system comprising a non-volatile memory device;
a controller coupled with the memory system and operable to cause the apparatus to:
store a set of temperature ranges and a set of partitions of the memory system, wherein each temperature range of the set of temperature ranges maps to one or more respective partitions of the set of partitions;
receive a command to read a partition of the set of partitions;
determining whether temperature data associated with the set of temperature ranges for the partition indicates that data was written to the partition outside a threshold temperature; and
reading data from the partition based at least in part on the determining whether the temperature data associated with the set of temperature ranges indicates that the data was written to the partition outside of the threshold temperature.

2. The apparatus of claim 1, wherein the controller is further configured to cause the apparatus to:
perform a garbage collection procedure on a first one or more partitions of the set of partitions before performing the garbage collection procedure on a second one or more partitions of the set of partitions based at least in part on determining that the first one or more partitions include data written at a temperature outside the threshold temperature and determining that the second one or more partitions include data written at a temperature within the threshold temperature.

3. The apparatus of claim 1, wherein the controller is further configured to cause the apparatus to:
write data to the partition; and
write an indication of a temperature range of the set of temperature ranges that corresponds to a temperature of the memory system that is associated with writing the data to the partition, wherein the temperature data for the partition includes the indication of the temperature range that corresponds to the temperature.

4. The apparatus of claim 1, wherein, to read the data from the partition, the controller is further configured to cause the apparatus to:
perform a temperature compensation procedure on the data based at least in part on determining that the temperature data for the partition indicates that the data was written to the partition outside the threshold temperature, the temperature compensation procedure comprising adjusting one or more aspects of the data based at least in part on a temperature range of the set of temperature ranges in which the data was written at the memory system.

5. The apparatus of claim 1, wherein, to read the data from the partition, the controller is further configured to cause the apparatus to:
refrain from performing a temperature compensation procedure for the data based at least in part on determining that the temperature data for the partition indicates that the data was written to the partition inside the threshold temperature.

6. The apparatus of claim 1, wherein, to store the set of temperature ranges and the set of partitions, the controller is further configured to cause the apparatus to:
partition the memory system into the set of partitions; and
set the set of temperatures ranges corresponding to the set of partitions of the partitioned memory system.

7. The apparatus of claim 1, wherein the controller is further configured to cause the apparatus to:
determine a table of the set of temperature ranges mapped to the set of partitions, wherein determining whether the temperature data associated with the set of temperature ranges for the partition indicates that the data was written to the partition outside the threshold temperature comprises reading one or more entries of the table and corresponding to the partition.

8. The apparatus of claim 1, wherein the temperature data is stored in a first portion of the memory system different than a second portion of the memory system that stores the data.

9. The apparatus of claim 8, wherein the first portion of the memory system comprises memory cells having a first number of one or more levels, and the second portion of the memory system comprises memory cells having a second number of levels greater than the first number of one or more levels.

10. The apparatus of claim 9, wherein the memory cells having the first number of one or more levels comprise single-level cells, and the memory cells having the second number of levels comprise quad-level cells.

11. The apparatus of claim 1, wherein the controller is further configured to cause the apparatus to:
update the partition; and
update the temperature data associated with the partition before writing new data to the partition.

12. The apparatus of claim 1, wherein the memory system comprises one or more non-volatile memory devices.

13. The apparatus of claim 1, wherein the memory system comprises one or more not- and memory devices.

14. A non-transitory computer-readable medium storing code comprising instructions which, when executed by a processor of an electronic device, cause the electronic device to:
store a set of temperature ranges and a set of partitions of a memory system, wherein each temperature range of the set of temperature ranges maps to one or more respective partitions of the set of partitions;
receive a command to read a partition of the set of partitions;
determine whether temperature data associated with the set of temperature ranges for the partition indicates that data was written to the partition outside a threshold temperature; and
read data from the partition based at least in part on the determining whether the temperature data associated with the set of temperature ranges indicates that the data was written to the partition outside of the threshold temperature.

15. The non-transitory computer-readable medium of claim 14, wherein, the instructions, when executed by the processor of the electronic device, further cause the electronic device to:
perform a garbage collection procedure on a first one or more partitions of the set of partitions before performing the garbage collection procedure on a second one or more partitions of the set of partitions based at least in part on determining that the first one or more partitions include data written at a temperature outside the threshold temperature and determining that the second one or more partitions include data written at a temperature within the threshold temperature.

16. The non-transitory computer-readable medium of claim 14, wherein, the instructions, when executed by the processor of the electronic device, further cause the electronic device to:
write data to the partition; and
write an indication of a temperature range of the set of temperature ranges that corresponds to a temperature of the memory system that is associated with writing the data to the partition, wherein the temperature data for the partition includes the indication of the temperature range that corresponds to the temperature.

17. The non-transitory computer-readable medium of claim 14, wherein, to read the data from the partition, the instructions, when executed by the processor of the electronic device, further cause the electronic device to:
perform a temperature compensation procedure on the data based at least in part on determining that the temperature data for the partition indicates that the data was written to the partition outside the threshold temperature, the temperature compensation procedure comprising adjusting one or more aspects of the data based at least in part on a temperature range of the set of temperature ranges in which the data was written at the memory system.

18. The non-transitory computer-readable medium of claim 14, wherein, to read the data from the partition, the instructions, when executed by the processor of the electronic device, further cause the electronic device to:
refrain from performing a temperature compensation procedure for the data based at least in part on determining that the temperature data for the partition indicates that the data was written to the partition inside the threshold temperature.

19. The non-transitory computer-readable medium of claim 14, wherein, to store the set of temperature ranges and the set of partitions, the instructions, when executed by the processor of the electronic device, further cause the electronic device to:
partition the memory system into the set of partitions; and
set the set of temperatures ranges corresponding to the set of partitions of the partitioned memory system.

20. The non-transitory computer-readable medium of claim 14, wherein, the instructions, when executed by the processor of the electronic device, further cause the electronic device to:
determine a table of the set of temperature ranges mapped to the set of partitions, wherein determining whether the temperature data associated with the set of temperature ranges for the partition indicates that the data was written to the partition outside the threshold temperature comprises reading one or more entries of the table and corresponding to the partition.

21. A method, comprising:
storing a set of temperature ranges and a set of partitions of a memory system, wherein each temperature range of the set of temperature ranges maps to one or more respective partitions of the set of partitions;
receiving a command to read a partition of the set of partitions;
determining whether temperature data associated with the set of temperature ranges for the partition indicates that data was written to the partition outside a threshold temperature; and
reading data from the partition based at least in part on the determining whether the temperature data associated with the set of temperature ranges indicates that the data was written to the partition outside of the threshold temperature.

22. The method of claim 21, further comprising:
performing a garbage collection procedure on a first one or more partitions of the set of partitions before performing the garbage collection procedure on a second one or more partitions of the set of partitions based at least in part on determining that the first one or more partitions include data written at a temperature outside the threshold temperature and determining that the second one or more partitions include data written at a temperature within the threshold temperature.

23. The method of claim 21, further comprising:
writing data to the partition; and
writing an indication of a temperature range of the set of temperature ranges that corresponds to a temperature of the memory system that is associated with writing the data to the partition, wherein the temperature data for the partition includes the indication of the temperature range that corresponds to the temperature.

24. The method of claim 21, wherein reading the data from the partition further comprises:
performing a temperature compensation procedure on the data based at least in part on determining that the temperature data for the partition indicates that the data was written to the partition outside the threshold temperature, the temperature compensation procedure comprising adjusting one or more aspects of the data based at least in part on a temperature range of the set of temperature ranges in which the data was written at the memory system.

25. The method of claim 21, wherein reading the data from the partition further comprises:
refraining from performing a temperature compensation procedure for the data based at least in part on determining that the temperature data for the partition indicates that the data was written to the partition inside the threshold temperature.
